(19) United States
(12) Patent Application Publication
(10) Pub. No.: US 2023/0326783 A1
(43) Pub. Date: Oct. 12, 2023

(54) SUBSTRATE PROCESSING APPARATUS INCLUDING SUBSTRATE TRANSFER ROBOT

(71) Applicant: ASM IP Holding B.V., Almere (NL)

(72) Inventors: Kazuhiro Nishiwaki, Tokyo (JP); Takahiro Murakami, Tokyo (JP)

(21) Appl. No.: 18/131,552

(22) Filed: Apr. 6, 2023

Related U.S. Application Data
(60) Provisional application No. 63/329,605, filed on Apr. 11, 2022.

(51) Int. Cl. H01L 21/687; H01L 21/67; B25J 11/00; B25J 13/08

(52) U.S. Cl. CPC H01L 21/68707; B25J 13/08; B25J 11/0095; H01L 21/67259

(57) ABSTRACT

A substrate processing apparatus is disclosed. Exemplary substrate processing apparatus includes a plurality of reaction chambers; a plurality of susceptors disposed within the reaction chambers and configured to support a substrate; a substrate transfer robot disposed within the substrate processing apparatus, comprising: a rotation arm comprising a plurality of arms, the arms configured to transfer the substrate between the reaction chambers; and a rotation shaft connected to the plurality of arms; a motor configured to rotate the rotation shaft; a motor controller configured to drive the motor; and a first sensor with a portion disposed on at least one of the plurality of arms.

### CROSS-REFERENCE TO RELATED APPLICATIONS

This application claims priority to U.S. Provisional Patent Application Ser. No. 63/329,605 filed Apr. 11, 2022 titled SUBSTRATE PROCESSING APPARATUS INCLUDING SUBSTRATE TRANSFER ROBOT, the disclosure of which is hereby incorporated by reference in its entirety.

### FIELD OF INVENTION

The present disclosure relates generally to a substrate processing apparatus. More particularly, exemplary embodiments of the present disclosure relate to a substrate processing apparatus including a substrate transfer robot.

### BACKGROUND OF THE DISCLOSURE

Substrate processing apparatuses are widely used to process substrates, for example, to form thin films on a substrate. The semiconductor processing apparatus often includes (i) a plurality of process modules; (ii) a substrate handling chamber having a substrate handling robot; and (iii) a load lock chamber for loading or unloading the substrate.

Each process module may include 4 reaction chambers. An exemplary substrate processing apparatus including 4 reaction chambers, which is known as a Quad Chamber Module (QCM), is disclosed in U.S. Pat. No. 10,777,445, which is hereby incorporated by reference.

Each chamber may include a susceptor to support a substrate. Processing, such as film formation, film modification, etching, or the like, may be performed on the substrate in each chamber. The substrate may be transferred from a certain chamber of the QCM to another chamber by a substrate transfer robot.

Misalignment of the substrate may occur in the chamber. There is a need to detect the misalignment to prevent any errors in the processing of the substrate.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a substrate processing apparatus is provided. The substrate processing apparatus may comprise a plurality of reaction chambers; a plurality of susceptors disposed within the reaction chambers and configured to support a substrate; a substrate transfer robot disposed within the substrate processing apparatus, comprising: a rotation arm comprising a plurality of arms, the arms configured to transfer the substrate between the reaction chambers; and a rotation shaft connected to the plurality of arms; a motor configured to rotate the rotation shaft; a motor controller configured to drive the motor; and a first sensor with a portion disposed on at least one of the plurality of arms.

In various embodiments, the first sensor may comprise a target object disposed on the at least one of the plurality of arms. The target object may be conical in shape.

In various embodiments, the substrate processing apparatus may further comprise a capacitive sensor disposed on a bottom of the reaction chamber.

In various embodiments, the substrate processing apparatus may further comprise a center plate; a plurality of screws; wherein the rotation arm is connected to the rotation shaft via the center plate by screws.

In various embodiments, the capacitive sensor may be configured to generate an electrostatic field to the target object when the motor rotates the rotation shaft, and the substrate is not on the susceptor.

In various embodiments, the substrate processing apparatus may further comprise a sensor controller configured to alert a signal based on an output of the capacitive sensor.

In various embodiments, the motor controller may be configured to stop the motor based on an output of the capacitive sensor.

In various embodiments, the substrate processing apparatus may further comprise a photoelectric sensor disposed between the center plate and the motor, wherein the photoelectric sensor is configured to detect a phase angle of the motor.

In various embodiments, the first sensor may comprise a capacitive sensor.

In various embodiments, the capacitive sensor may be configured to generate an electrostatic field to the substrate on the susceptor when the motor rotates the rotation shaft.

In various embodiments, the substrate processing apparatus may further comprise a sensor controller configured to alert a signal based on an output of the capacitive sensor.

In various embodiments, the motor controller may be configured to stop the motor based on an output of the capacitive sensor.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 is a schematic plan view of a semiconductor processing apparatus with quad chamber modules usable in an embodiment of the present invention.

FIG. 2 is a schematic cross-sectional view of a quad chamber module in an embodiment of the present invention.

FIG. 3 is a schematic perspective view of a substrate transfer robot in an embodiment of the present invention.

FIG. 4 is a schematic cross-sectional view of a reaction chamber in an embodiment of the present invention.

FIG. 5A is a schematic graph of a capacitive sensor output in an embodiment of the present invention.

FIG. 5B is a schematic graph showing a variation of a capacitive sensor output in an embodiment of the present invention.

FIG. 6 is a schematic cross-sectional perspective view of a quad chamber module in another embodiment of the present invention.

FIG. 7 is a schematic plan view of a reaction chamber in another embodiment of the present invention.

It will be appreciated that elements in the figures are illustrated for simplicity and clarity and have not necessarily been drawn to scale. For example, the dimensions of some of the elements in the figures may be exaggerated relative to other elements to help understanding of illustrated embodiments of the present disclosure.

### DETAILED DESCRIPTION OF EXEMPLARY EMBODIMENTS

Although certain embodiments and examples are disclosed below, it will be understood by those in the art that the disclosure extends beyond the specifically disclosed embodiments and/or uses of the disclosure and obvious modifications and equivalents thereof. Thus, it is intended that the scope of the disclosure should not be limited by the particular embodiments described herein.

The illustrations presented herein are not meant to be actual views of any particular material, apparatus, structure, or device, but are merely representations that are used to describe embodiments of the disclosure.

In this disclosure, “gas” may include material that is a gas at normal temperature and pressure, a vaporized solid and/or a vaporized liquid, and may be constituted by a single gas or a mixture of gases, depending on the context. A gas introduced without passing through a gas supply unit, such as a shower plate, or the like, may be used for, e.g., sealing the reaction space, and may include a seal gas, such as a rare or other inert gas. The term inert gas may refer to a gas that does not take part in a chemical reaction to an appreciable extent and/or a gas that can excite a precursor when plasma power is applied.

As used herein, the term “substrate” may refer to any underlying material or materials that may be used, or upon which, a device, a circuit, or a film may be formed, which is typically a semiconductor wafer.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

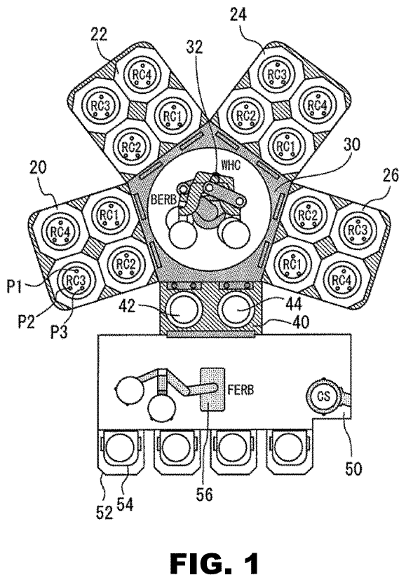

FIG. 1 is a schematic plan view of a substrate processing apparatus with quad chamber modules in an embodiment of the present invention. The substrate processing apparatus may comprise: (i) four process modules 20, 22, 24, 26, each having four reaction chambers RC1, RC2, RC3, RC4; (ii) a substrate handling chamber 30 including two back end robots 32 (substrate handling robots); and (iii) a load lock chamber 40 for loading or unloading two substrates simultaneously, the load lock chamber 40 being attached to the one additional side of the substrate handling chamber 30, wherein each back end robot 32 is accessible to the load lock chamber 40. Each of the back end robots 32 have at least two end-effectors accessible to the two reaction chambers of each unit simultaneously, said substrate handling chamber 30 having a polygonal shape having four sides corresponding to and being attached to the four process modules 20, 22, 24, 26, respectively, and one additional side for a load lock chamber 40, all the sides being disposed on the same plane. The interior of each process modules 20, 22, 24, 26 and the interior of the load lock chamber 40 may be isolated from the interior of the substrate handling chamber 30 by a gate valve.

In some embodiments, a controller (not shown) may store software programmed to execute sequences of substrate transfer, for example. The controller may also: check the status of each process chamber; position substrates in each process chamber using sensing systems, control a gas box, and an electric box for each module; control a front end robot 56 in an equipment front end module based on a distribution status of substrates stored in FOUP 52 and the load lock chamber 40; control the back end robots 32; and the control gate valves and other valves.

A skilled artisan may appreciate that the apparatus includes one or more controller(s) programmed or otherwise configured to cause the deposition and reactor cleaning processes described elsewhere herein to be conducted. The controller(s) may communicate with the various power sources, heating systems, pumps, robotics, gas flow controllers, or valves, as will be appreciated by the skilled artisan.

In some embodiments, the apparatus may have any number of reaction chambers and process modules greater than one (e.g., 2, 3, 4, 5, 6, or 7). In FIG. 1, the apparatus has sixteen reaction chambers, but it may have 20 or more. In some embodiments, the reactors of the modules may be any suitable reactors for processing or treating wafers, including CVD reactors (such as plasma-enhanced CVD reactors and thermal CVD reactors) or ALD reactors (such as plasma-enhanced ALD reactors and thermal ALD reactors). Typically, the reaction chambers may comprise plasma reactors for depositing a thin film or layer on a wafer. In some embodiments, all the modules may have identical capabilities for treating wafers so that the unloading/loading can sequentially and regularly be timed, thereby increasing productivity or throughput. In some embodiments, the modules may have different capabilities (e.g., different treatments) but their handling times may be substantially identical.

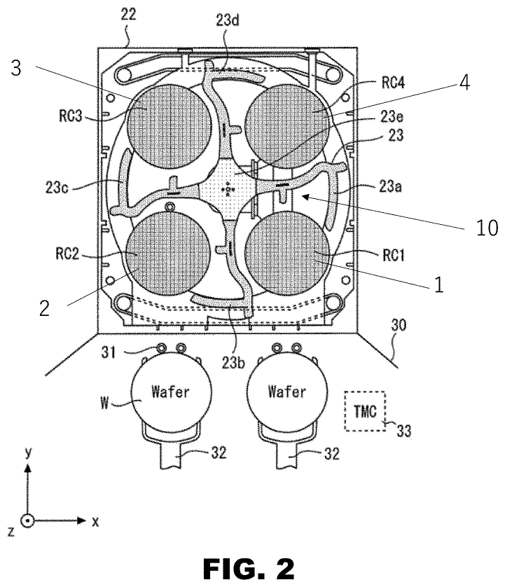

FIG. 2 is a schematic cross-sectional view of a quad chamber module in an embodiment of the present invention. The substrate processing apparatus includes four reaction chambers RC1, RC2, RC3, RC4; four susceptors 1, 2, 3, 4 disposed within the reaction chambers RC1, RC2, RC3, RC4 and configured to support a substrate W; and a substrate transfer robot 10.

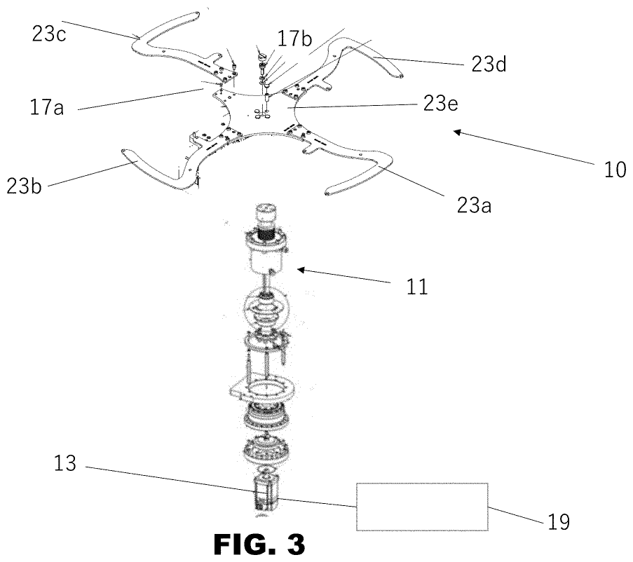

FIG. 3 is a schematic perspective view of a substrate transfer robot in an embodiment of the present invention. The substrate transfer robot 10 includes a rotation arm comprising four arms 23a, 23b, 23c, 23d, which transfer the substrate between the reaction chambers; a rotation shaft 11 connected to the arms; a motor 13 configured to rotate the rotation shaft 11 and a motor controller 19 configured to drive the motor. The substrate transfer robot 10 may further comprise a center plate 23e and a plurality of screws 17a, 17b. Each rotation arm 23a, 23b, 23c, 23d may be connected to the rotation shaft 11 via the center plate 23e by screws 17a, 17b.

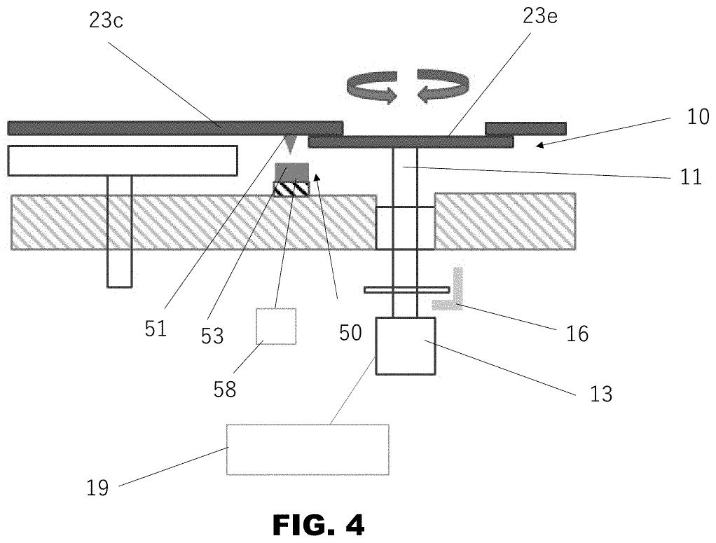

FIG. 4 is a schematic cross-sectional view of a reaction chamber in an embodiment of the present invention. The substrate transfer robot 10 further includes a first sensor 50 with a portion disposed on at least one of the plurality of arms. The first sensor 50 may comprise a target object 51. The target object 51 may be conical in shape.

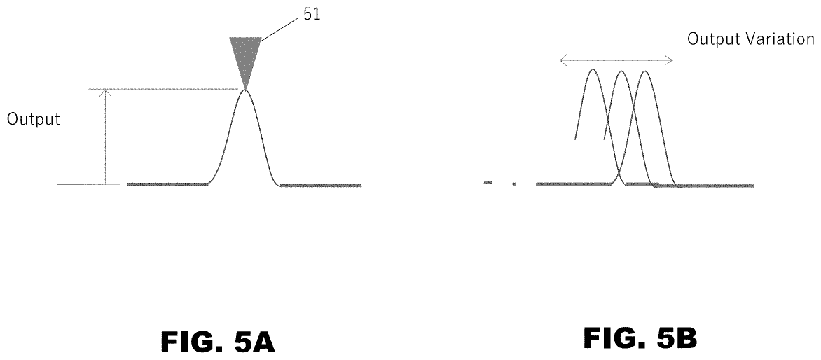

The substrate processing apparatus further includes a capacitive sensor 53 disposed on a bottom of the reaction chamber. The capacitive sensor 53 may be configured to generate an electrostatic field to the target object 51 when the motor 13 rotates the rotation shaft 11, and the substrate is not on the susceptor. FIG. 5A is a schematic graph showing a normal output of the capacitive sensor in an embodiment of the present invention.

FIG. 5B is a schematic graph showing a variation of a capacitive sensor output in an embodiment of the present invention. If at least one of the screws 17a, 17b is not properly tighten, at least one of the rotation arms 23a, 23b, 23c, 24d may not be in the right place, resulting in a variation of the output. A sensor controller 58 may be configured to alert a signal based on a variation of the output. The motor controller 19 may be configured to stop the motor 13 based on a variation of the output.

As shown in FIG. 4, the substrate processing apparatus may further comprise a photoelectric sensor 16 disposed between the center plate 23e and the motor 13. The photoelectric sensor 16 may be configured to detect a phase angle of the motor, but cannot detect whether the screws 17a, 17b are properly tighten.

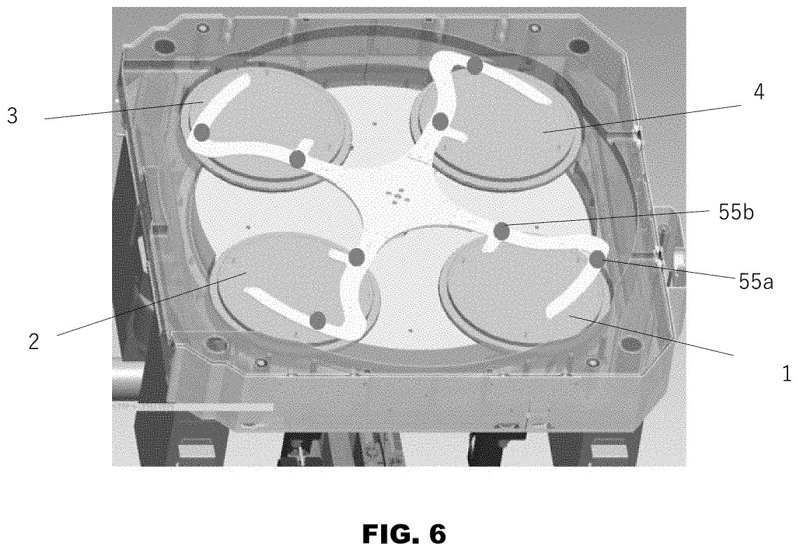

FIG. 6 is a schematic cross-sectional view of a quad chamber module in another embodiment of the present invention. In this embodiment, the first sensor 50 may comprise a capacitive sensors 55a and 55b.

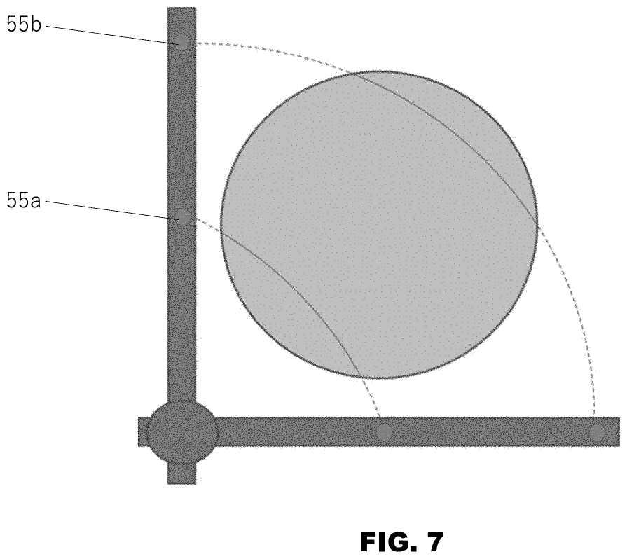

FIG. 7 is a schematic plan view of a reaction chamber in another embodiment of the present invention. The capacitive sensors 55a, 55b may be configured to generate an electrostatic field to the substrate on the susceptor when the motor 13 rotates the rotation shaft 11. If a substrate is not in the right place, it will result in a variation of the output.

As well as the first embodiment, the capacitive sensors can include a sensor controller configured to alert a signal based on a variation of the output. The motor controller may be configured to stop the motor based on a variation of the output.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A substrate processing apparatus, comprising:
a plurality of reaction chambers;
a plurality of susceptors disposed within the reaction chambers and configured to support a substrate;
a substrate transfer robot disposed within the substrate processing apparatus, comprising:
a rotation arm comprising a plurality of arms, the arms configured to transfer the substrate between the reaction chambers;
a rotation shaft connected to the plurality of arms;
a motor configured to rotate the rotation shaft;
a motor controller configured to drive the motor; and
a first sensor with a portion disposed on at least one of the plurality of arms.

2. The substrate processing apparatus according to claim 1, wherein the first sensor comprises a target object disposed on the at least one of the plurality of arms.

3. The substrate processing apparatus according to claim 2, wherein the target object is conical shape.

4. The substrate processing apparatus according to claim 2, further comprising a capacitive sensor disposed on a bottom of the reaction chamber.

5. The substrate processing apparatus according to claim 1, further comprising:
a center plate;
a plurality of screws;
wherein the rotation arm is connected to the rotation shaft via the center plate by screws.

6. The substrate processing apparatus according to claim 4, wherein the capacitive sensor is configured to generate an electrostatic field to the target object when the motor rotates the rotation shaft, and the substrate is not on the susceptor.

7. The substrate processing apparatus according to claim 6, further comprising a sensor controller configured to alert a signal based on an output of the capacitive sensor.

8. The substrate processing apparatus according to claim 6, wherein the motor controller is configured to stop the motor based on an output of the capacitive sensor.

9. The substrate processing apparatus according to claim 6, further comprising a photoelectric sensor disposed between the center plate and the motor, wherein the photoelectric sensor is configured to detect a phase angle of the motor.

10. The substrate processing apparatus according to claim 1, wherein the first sensor comprises a capacitive sensor.

11. The substrate processing apparatus according to claim 10, wherein the capacitive sensor is configured to generate an electrostatic field to the substrate on the susceptor when the motor rotates the rotation shaft.

12. The substrate processing apparatus according to claim 10, further comprising a sensor controller configured to alert a signal based on an output of the capacitive sensor.

13. The substrate processing apparatus according to claim 11, wherein the motor controller is configured to stop the motor based on an output of the capacitive sensor.
